(19) United States
(12) Patent Application Publication
(10) Pub. No.: US 2023/0200249 A1
(43) Pub. Date: Jun. 22, 2023

(54) FLUID CONTROL DEVICE, VAPORIZATION SYSTEM, AND PIEZO ACTUATOR

(71) Applicant: HORIBA STEC, Co., Ltd., Kyoto-shi (JP)

(72) Inventors: Takayuki INOUE, Sendai-shi (JP); Noriaki IKEZAWA, Sendai-shi (JP); Akihiro TAGUCHI, Kyoto-shi (JP); Toshihiro IKEYAMA, Kyoto-shi (JP); Tsuyoshi ICHINOMIYA, Kyoto-shi (JP); Akihiro NAKAMURA, Kyoto-shi (JP)

(21) Appl. No.: 18/055,774

(22) Filed: Nov. 15, 2022

(30) Foreign Application Priority Data
Dec. 21, 2021 (JP) 2021-207113

(51) Int. Cl. H01L 41/083; H01L 41/047

(52) U.S. Cl. CPC H01L 41/0838; H01L 41/0472

(57) ABSTRACT

The present invention is one which prevents the occurrence of cracks in piezo elements and reduces the thermal effects on the control board, and comprises a fluid control valve driven by a piezo actuator, a fluid sensor which measures the pressure or flow rate of the fluid, a control board which controls the fluid control valve based on the measured value measured by the fluid sensor, and a discharge resistor provided on a component different from the control board.

### TECHNICAL FIELD

The present invention relates to a fluid control device, a vaporization system making use of the fluid control device, and a piezo actuator made use of therein.

### BACKGROUND ART

As shown in Patent Literature 1, a conventional fluid control device using a piezo actuator as a fluid control valve has been considered.

This piezo actuator has a piezo stack in which a large number of piezo elements are stacked. If a crack occurs in the piezo elements, a short circuit occurs between the piezo elements, resulting in failure.

Such cracks can be caused not only by an impact due to an external force, but also by rapid charging and discharging of the piezo elements. Therefore, in order to prevent rapid charging and discharging, a discharge resistor is mounted on the control board, and the discharge resistor is connected in parallel to the positive terminal and the negative terminal of the piezo actuator.

Moreover, besides an application of voltage and an electrical discharge of the control board, a pyroelectric effect due to temperature change and a piezoelectric effect due to external force can be given as examples of the cause of charging and discharging.

However, when a discharge resistor is provided in the control board, resistive heat generated by the discharge resistor adversely affects other elements mounted on the control board.

### PRIOR ART DOCUMENTS

### Patent Documents

Patent Document 1: International Publication No. 2020/066491

### SUMMARY OF THE INVENTION

### Problems to be Solved by the Invention

Accordingly, the present invention has been made in view of the above problems, and its main object is to prevent cracks from occurring in the piezo elements and to reduce thermal effects on the control board.

### Means for Solving the Problems

That is, a fluid control device according to the present invention includes a fluid control valve driven by a piezo actuator, a fluid sensor which measures a pressure or a flow rate of a fluid, a control board which controls the fluid control valve based on a measured value measured by the fluid sensor, and a discharge resistor provided on a component different from the control board.

With such a fluid control device, even if the piezo elements are charged by the pyroelectric effect due to temperature change or the piezoelectric effect due to external force, this can be discharged by the discharge resistor each time, and it is therefore possible to prevent the generation of cracks in the piezo elements. Furthermore, since the discharge resistor is provided on a component different from the control board, it is possible to reduce the thermal effects on the control board from resistive heat generated by the discharge resistor.

As a simple connection layout for discharging the piezo actuator, it is desirable that the discharge resistor is connected in parallel with the piezo actuator.

When the fluid control device is used in a high temperature environment, the problem of heat resistance of the control board arises. Therefore, in order to allow the fluid control device to be used even in a high-temperature environment, it is preferable that the configuration be such that the control board and the main unit which has the fluid control valve and the fluid sensor are separated, and the discharge resistor is provided in the main unit.

It is preferable that the discharge resistor is provided in a power supply terminal part which extends from a case which accommodates a piezo stack of the piezo actuator.

With this configuration, if conduction failure occurs in the discharge resistor, visual inspection is simple. In addition, the task of inserting the discharge resistor is simplified.

Specifically, it is preferable that the discharge resistor is formed by forming a resistive film on a substrate made of an insulating material such as ceramic, and the substrate is formed with a through hole to be attached to the power supply terminal part.

With this configuration, a conductive connection can be reliably made to the power supply terminal part via the through hole. In addition, since a gap or a substrate is interposed between the piezo stack of the piezo actuator and the resistive film, the influence of resistance heating on the piezo stack can be reduced.

It is desirable that the discharge resistor is provided within a case containing a piezo stack of the piezo actuator.

With this configuration, since the discharge resistor is provided inside the piezo actuator, the assembly of the fluid control device can be made to be the same as with a conventional configuration.

It is desirable that the main unit has a connection cable or a connector connected to the control board, and the discharge resistor is provided on the connection cable or the connector. With this configuration, it is easy to perform a visual inspection if a conduction failure occurs in the discharge resistor. Moreover, since the discharge resistor can be sufficiently separated from the piezo stack, it is possible to reduce the influence of resistance heating on the piezo stack. Furthermore, the discharge resistor can be separated from the high-temperature environment, and there is no need to use an expensive discharge resistor with heat resistance properties.

The main unit preferably has an internal board which processes signals from the fluid sensor, and the discharge resistor is preferably provided on the internal board.

With this configuration, it is possible to provide the discharge resistor in the main unit. Also, by providing the discharge resistor on the internal board, assembly becomes easier. Furthermore, visual inspection is easy if a conduction failure occurs in the discharge resistor.

A vaporization system according to the present invention is characterized by comprising a vaporizer part for vaporizing a liquid material, and the above-described fluid control device for controlling the flow rate of the gas vaporized by the vaporizer part.

Furthermore, a piezo actuator according to the present invention used for driving a fluid control valve in a fluid control device, the fluid control device comprising the fluid control valve, a fluid sensor that measures a pressure or a flow rate of a fluid, a control board that controls the fluid control valve based on a measured value measured by the fluid sensor, and a discharge resistor provided on a component different from the control board, and it is desirable that the discharge resistor is connected in parallel to a power supply terminal extending from a case housing a piezo stack of the piezo actuator.

As a specific embodiment of the discharge resistor, it is considered that the discharge resistor is configured by forming a resistive film on a substrate made of an insulating material. In this configuration, it is desirable that the substrate is formed with a through hole to be attached to the power supply terminal part.

### Effects of the Invention

According to the present invention described above, it is possible to prevent cracks from occurring in the piezo elements and to reduce the thermal effects on the control board.

### BRIEF DESCRIPTION OF THE DRAWINGS

FIG. 1 is a schematic diagram showing the composition of the fluid control device relating to a first embodiment of the present invention.

FIGS. 2(a) and 2(b) are schematic diagrams which show installation example 1 of the discharge resistor of the same embodiment.

FIG. 3 is a diagram showing a variation of installation example 1.

FIG. 4 is a schematic diagram which shows installation example 2 of the discharge resistor of the same embodiment.

FIGS. 5(a) and 5(b) are schematic diagrams which show installation example 3 of the discharge resistor of the same embodiment.

FIG. 6 is a schematic diagram which shows installation example 4 of the discharge resistor of the same embodiment.

FIG. 7 is a schematic diagram showing the configuration of a vaporization system incorporating the fluid control device of the present invention.

### EMBODIMENTS FOR CARRYING OUT THE INVENTION

Each embodiment of the present invention will be described below with reference to the drawings. It should be noted that all of the drawings shown below are schematically drawn with appropriate omissions or exaggerations for the sake of clarity. The same components are given the same reference numerals, and the description thereof is omitted as appropriate.

### Embodiment 1

To begin with, the first embodiment of the fluid control device according to the present invention is described with reference to the drawings.

### <Device Configuration>

The fluid control device 100 of the present embodiment is a so-called mass flow controller and is used, for example, to control the flow rate of gas supplied to a chamber for performing a semiconductor manufacturing process. Moreover, the fluid control device 100 may control a liquid rather than only gases.

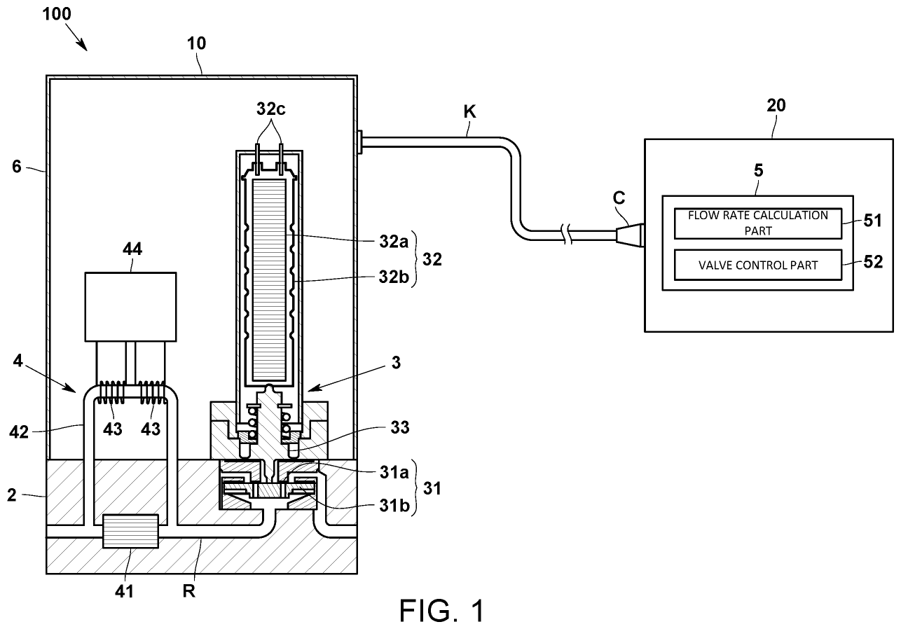

Specifically, as shown in FIG. 1, the fluid control device 100 includes a body 2 in whose interior a flow path R is formed, a fluid control valve 3 for controlling the fluid in the flow path R, a flow rate sensor 4 which measures a flow rate in the flow path R, and a control board 5 which controls the fluid control valve 3 based on a measured value measured by the flow sensor 4.

As shown in FIG. 1, the fluid control valve 3 and the flow rate sensor 4 of the present embodiment are equipped on a surface (for example, an upper surface) of the body 2 and housed inside of a cover 6 which is attached to a surface of the body 2, as shown in FIG. 1. The fluid control valve 3 and the flow rate sensor 4 are thereby packaged as a main unit 10. Moreover, the control unit 20, which has the control board 5, is provided separately from the main unit 10 and is connected by a connector cable K in order to control each part of the main unit 10. Furthermore, the connector cable K is detachably connected to at least the control unit 20.

In this configuration, when the fluid control device 100 is used in a high-temperature environment, while the main unit 10 is used in the high-temperature environment, the control unit 20 is placed away from the high-temperature environment. This allows the issue of the heat-resistive properties of the control board 5 to be resolved. Further, the fluid control device 100 is separately packaged and installed as the main unit 10 and the control unit 20 during transport and installation.

The fluid control valve 3 is a so-called piezo valve whose extent of opening is controlled by an applied voltage. Specifically, the fluid control valve 3 comprises a valve mechanism 31 made up of a valve seat 31a and a valve body 31b which are accommodated in a concave part on an upper surface of the body 2, a piezo actuator 32 that exerts a driving force to change the position of the valve body 31b with respect to the valve seat 31a, and a plunger 33 which connects the space between the valve mechanism 31 and the piezo actuator 32. Furthermore, in the present embodiment the fluid control valve 3 is a normally-opened type, but it may also be a normally-closed type. Additionally, the configuration of the valve mechanism 31 is not limited to what is described above, as a configuration in which the valve seat 31a or the valve body 31b is housed in a concave part formed in the upper surface of the body 2 may also be used, or configuration in which a valve seat is formed on the upper surface of the body 2.

The piezo actuator 32 has a piezo stack 32a which has been structured by stacking a large number of sheet-shaped piezo elements which expand in the sheet thickness direction when an electric current is applied, and a case 32b that accommodates the piezo stack 32a. Each piezo element is composed of a sheet-shaped piezoelectric ceramic body and electrode bodies provided on both sides of the piezoelectric ceramic body. This piezo actuator 32 is voltage-driven by a drive circuit which is not shown in the figures. Moreover, the drive circuit outputs a voltage which corresponds to a command voltage outputted from the control board 5.

The flow rate sensor 4 is a thermal-type one, and has a flow dividing element (a resistive element) 41 provided in the flow path R, a thin tube 42 that branches from the upstream side of the flow dividing element 41 and merges with the downstream side of the flow dividing element 41, two electric heating coils 43 wound around the thin tube 42 and each having a voltage applied to them so that they are kept at a constant temperature, and a detection circuit 44 which detects the difference in voltage applied to each of the electric heating coils 43. The flow rate sensor 4 is provided upstream or downstream of the fluid control valve 3 in the flow path R. Note that the flow rate sensor 4 may be of a type other than thermal, and could be of a pressure-type, for example.

The control board 5 controls the fluid control valve 3 based on the flow rate measured by the flow rate sensor 4. This control board 5 is a computer equipped with a CPU, a memory, an A/D converter, a D/A converter, and various input/output means; a fluid control program stored in the memory is executed, and the functions of a flow rate calculation unit 51 and a valve control unit 52, etc., are exhibited by the cooperation of the CPU and the peripheral devices.

The flow rate calculation unit 51 calculates the flow rate of gas flowing through the flow path R based on the output of the detection circuit 44 of the flow rate sensor 4.

The valve control unit 52 controls the extent of opening of the fluid control valve 3 based on the externally-inputted command flow rate and the measured flow rate measured by the flow rate sensor 4. Specifically, the valve control unit 52 controls the extent of opening of the fluid control valve 3 so that the deviation between the command flow rate and the measured flow rate is minimized. The valve control unit 52 of the present embodiment performs a PID calculation on the deviation between the command flow rate and the measured flow rate, and outputs a command voltage according to the result to the drive circuit of the piezo actuator 32. The drive circuit applies a voltage corresponding to the inputted command voltage to the piezo stack 32a.

### <Configuration of Discharge Resistor 7>

As described above, the fluid control device 100 is separately packaged and installed as the main unit 10 and the control unit 20 during transport and installation. Temperature changes are especially large during transportation, and the piezo stack 32a is electrically charged due to the pyroelectric effect. The piezo stack 32a is also charged by the piezoelectric effect due to vibration during transportation. Later on, for example, if there is a short circuit or the like in the piezo stack 32a during installation, there is a possibility that there will be a sudden discharge and cracks will occur in the piezo elements of the piezo stack 32a.

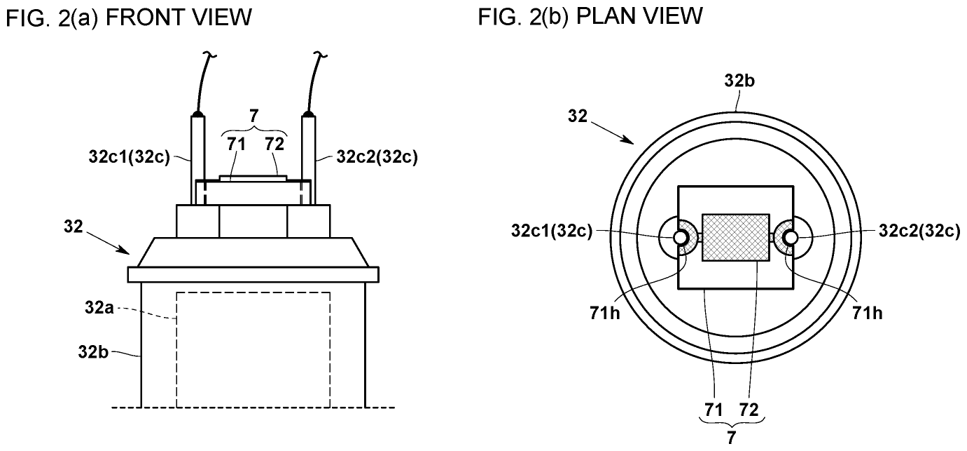

For this reason, the fluid control device 100 of the present embodiment further includes a discharge resistor 7 provided on a component different from the control board 5, as shown in FIGS. 2(a) and 2(b)-6. This discharge resistor 7 is provided in the main unit 10 and connected in parallel to the piezo actuator 32.

Since the discharge resistor 7 is provided in this manner, even if the piezo stack 32a is charged by the pyroelectric effect due to temperature change or the piezoelectric effect due to external force, the discharge resistor 7 can discharge the piezo stack 32a. As a result, it is possible to prevent cracks from occurring in the piezo elements of the piezo stack 32a. Moreover, since the discharge resistor 7 is provided on a component different from the control board 5, the thermal effects of the discharge resistor 7 on the control board 5 due to the resistance heat generation can be reduced.

The configuration of the discharge resistor 7 will now be described in detail.

In the configuration shown in FIG. 2(a), the discharge resistor 7 is provided in a power supply terminal part 32c extending from the case 32b housing the piezo stack 32a of the piezo actuator 32. The power supply terminal portion 32c is a so-called hermetic terminal, and extends from the upper surface of the case 32b, and consists of a positive terminal 32c1 and a negative terminal 32c2. The discharge resistor 7 is connected to the positive terminal 32c1 and the negative terminal 32c2.

Specifically, as shown in FIGS. 2(a) and 2(b), the discharge resistor 7 is constructed by forming a resistive film 72 on a substrate 71 made of an insulating material such as ceramic. As shown in FIG. 2(b), the substrate 71 has a substantially rectangular shape in a plan view, and is formed with through holes 71h to be attached to the power supply terminal part 32c. The through holes 71h are formed in semicircular shapes on the sides of the substrate 71 facing each other. The discharge resistor 7 configured in this manner is arranged between the positive terminal 32c1 and the negative terminal 32c2, and is configured such that the positive terminal 32c1 and the negative terminal 32c2 are fitted in the two through holes 71h, respectively. The discharge resistor 7 is soldered to the positive terminal 32c1 and the negative terminal 32c2 at the through hole 71h.

Here, the value of the resistance of the resistive film 72 formed on the substrate 71 of the discharge resistor 7 can be varied in accordance with the insulation resistance of the piezo actuator 32. For example, the value of the resistance of the resistive film 72 could be 1 MΩ, 10 MΩ, or 100 MΩ. These can be achieved by changing the printed pattern of the resistive film 72. Furthermore, from the point of view of versatility, the shape of the substrate 71 (including through holes 71h) is the same regardless of the difference in the resistance value of the resistive film 72.

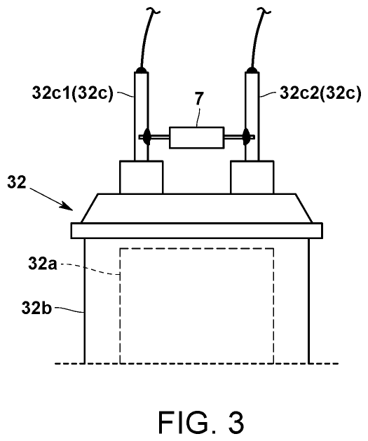

In addition, the discharge resistor 7 may have a structure in which a resistor is mounted on the substrate 71 rather than a structure in which a resistive film 72 is formed on the substrate 71. And, as shown in FIG. 3, it is also possible to connect a resistor to the positive terminal 32c1 and the negative terminal 32c2 without having a substrate 71.

With the configuration of FIGS. 2(a) and 2(b), conductive connections can be reliably made through the through holes 71h. With the configuration of FIGS. 2(a) and 2(b) and 3, it is easy to perform a visual inspection if a conduction failure occurs in the discharge resistor 7. In addition, since a gap and the substrate 71 are interposed between the piezo actuator 32 (piezo stack 32a) and the resistive film 72, the influence of resistive heating on the piezo stack 32a can be reduced.

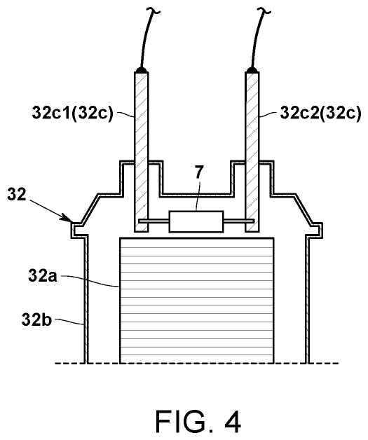

In the configuration shown in FIG. 4, the discharge resistor 7 is provided inside the case 32b that accommodates the piezo stack 32a of the piezo actuator 32. Specifically, the discharge resistor 7 is connected to the positive terminal 32c1 and the negative terminal 32c2 of the power supply terminal part 32c which extend inside the case 32b. Alternatively, if the discharge resistor 7 is inside the case 32b, it may be connected to internal wiring which is connected to the power supply terminal part 32c.

With the configuration of FIG. 4, since the discharge resistor 7 is provided inside the piezo actuator 32, the assembly of the fluid control device 100 can be the same as in a conventional configuration.

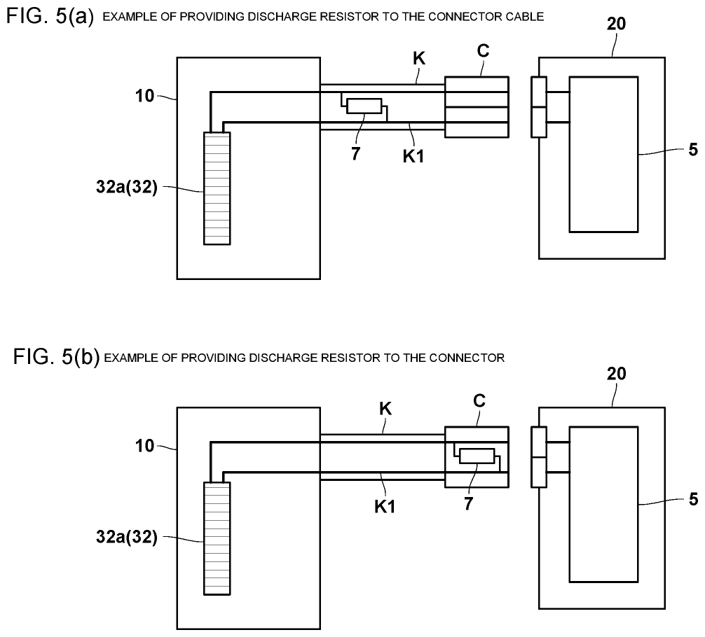

In the configuration shown in FIGS. 5(a) and 5(b), the discharge resistor 7 is provided on connector cable K or connector C of the main unit 10. If the discharge resistor 7 is provided to the connector cable K or the connector C, the discharge resistor 7 is connected to power line K1 connected to the power supply terminal part 32c of the piezo actuator 32 in the connector cable K or the connector C. FIG. 5(a) shows an example in which the discharge resistor 7 is connected to power line K1 in connector cable K, and FIG. 5(b) shows an example in which the discharge resistor 7 is connected to power line K1 in the connector C.

In the configuration of FIGS. 5(a) and 5(b), the discharge resistor 7 is connected to the power line K1, which simplifies assembly. In addition, if a conduction failure occurs in the discharge resistor 7, visual inspection is easy. Moreover, since the discharge resistor 7 can be sufficiently separated from the piezo stack 32a, it is possible to reduce the effects of resistive heating on the piezo stack 32a. Furthermore, the discharge resistor 7 can be kept away from a high-temperature environment, and there is no need to use an expensive discharge resistor 7 which has heat resisting properties.

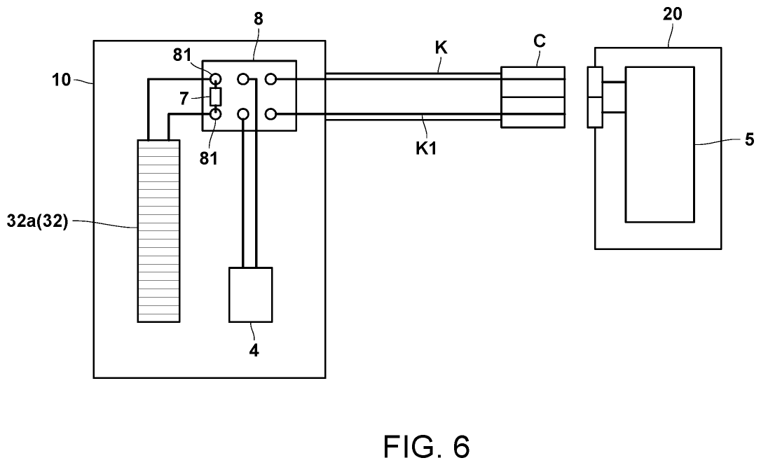

In the configuration shown in FIG. 6, the discharge resistor 7 is provided on a relay board 8 provided in the main unit 10. The relay board 8 is an internal board that processes a signal from the flow rate sensor 4, and relays the power line K1 to the connection cable K. The relay board 8 has connection pins 81 to which the power line K1 is connected, and the discharge resistor 7 is connected to the connection pins 81.

With the configuration of FIG. 6, the discharge resistor 7 can be provided inside the main unit 10. In addition, since the discharge resistor 7 is connected to the relay board 8, assembly is simplified. In addition, if a conduction failure occurs in the discharge resistor 7, visual inspection is easy.

### Embodiment 2

Next, an embodiment of a vaporization system incorporating the fluid control device according to the present invention will be described with reference to the drawings.

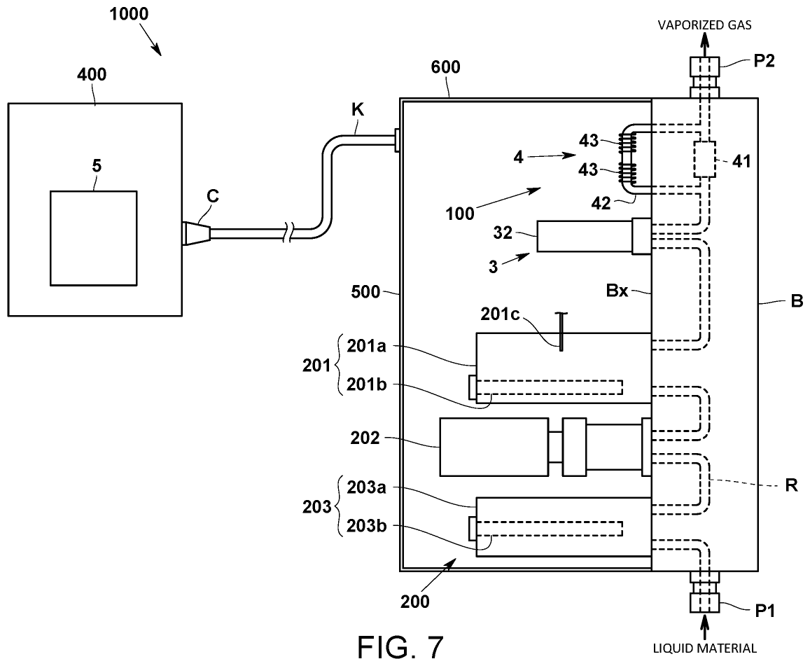

The vaporization system 1000 of the present embodiment is incorporated in, for example, a semiconductor manufacturing line or the like and supplies gas at a predetermined flow rate to a chamber in which a semiconductor manufacturing process is performed and, as shown in FIG. 7, includes a vaporizer part 200 for vaporizing a liquid material, a fluid control device 100 for controlling the flow rate of the gas which has been vaporized by the vaporizer part 200, and a control part 400 for controlling the operations of the vaporizer part 200 and the fluid control device 100. The configuration of the fluid control device 100 is the same as that of the first embodiment.

In this embodiment, the vaporizer part 200 and the fluid control device 100 are housed in a common housing 500 to form a vaporization unit 600, and the control device 400 is provided separately from the vaporization unit 600. The vaporization unit 600 and the control device 400 are connected by a connection cable K for controlling each part of the vaporization unit 600.

The vaporizer part 200 includes a vaporizer 201 that vaporizes the liquid material by, for example, the baking method, a supply amount control device 202 that controls the amount of liquid material supplied to the vaporizer 201, and a preheater 203 that preheats the liquid material supplied to the vaporizer 201 to a predetermined temperature.

The vaporizer 201, supply amount control device 202, and preheater 203 are mounted on a device mounting surface Bx set on one surface of a body block B in which a flow path R is formed. Here, the body block B is made of metal such as stainless steel, for example, and has a substantially rectangular parallelepiped shape having a longitudinal direction. This body block B has a liquid material introduction port P1 which is located on the lower side, and is installed in a semiconductor manufacturing line or the like so that a vaporized gas outlet port P2 is positioned on the upper side and the longitudinal direction is oriented in the up-down direction (the vertical direction).

The vaporizer 201 has a storage container 201a, which is a vaporization tank for storing the liquid material inside, and a vaporization heater 201b provided in the storage container 201a for vaporizing the liquid material. The storage container 201a is provided with a liquid level sensor 201c for detecting the amount of the stored liquid material.

The supply amount control device 202 is a control valve that controls the supply flow rate of liquid material to the vaporizer 201, and is an electromagnetic on-off valve in this embodiment. Specifically, it is configured such that a valve body (not shown) of the electromagnetic on-off valve 202 opens or closes an opening of an internal flow path formed in the body block B to supply or stop the supply of liquid material to the vaporizer 201.

The preheater 203 has a preheating block 203a in which a flow path through which the liquid material flows is formed, and a preheating heater 203b provided in the preheating block 203a for preheating the liquid material. The preheater 203 heats the liquid material to a temperature just before vaporization (below the boiling point).

The liquid material introduced from the liquid material introduction port P1 is preheated to a predetermined temperature by flowing through the flow path of the preheating block 203a of the preheater 203 via the vaporizer part 200 configured as described above. The liquid material preheated by the preheater 203 is introduced into the vaporizer 201 by controlling the electromagnetic on-off valve 202, which is a supply amount control device. In the vaporizer 201, the liquid material reaches a state in which it is continuously accumulated, the liquid material is vaporized, vaporized gas is continuously generated, and the vaporized gas is continuously delivered to the fluid control device 100.

The fluid control device 100, similarly to the vaporizer part 200, is mounted on a device mounting surface Bx set on one surface of the body block B. Specifically, the fluid control device 100 is provided on the body block B downstream of the vaporizer part 200. The configuration of fluid control device 100 is the same as that of the first embodiment.

The control device 400 controls the behavior of the vaporization of the liquid material by the vaporization system 1000. Specifically, the control device 400 is configured to supply the liquid material to the vaporizer 201 during vaporization operation by controlling the electromagnetic on-off valve 202 described above. The control device 400 is also configured to control the fluid control valve 3 based on the measured flow rate measured by the flow rate sensor 4. The control device 400 has the control board 5 of the first embodiment.

In this vaporization system 1000, the configuration of the discharge resistor 7 provided in the fluid control device 100 is also the same as that of the first embodiment.

Specifically, the configuration in which the discharge resistor 7 is provided in the power supply terminal part 32c of the piezo actuator 32 is the same as that shown in FIGS. 2(a) and 2(b) or FIG. 3, and the configuration in which the discharge resistor 7 is provided inside the case 32b of the piezo actuator 32 is the same as in FIG. 4.

Furthermore, in FIGS. 5(a) and 5(b), the body unit 10 is replaced with the vaporization unit 600, and the discharge resistor 7 is provided in the connection cable K or the connection connector C of the vaporization unit 600. Furthermore, in FIG. 6, the relay board 8 provided in the vaporization unit 600 is provided with the discharge resistor 7.

### OTHER EMBODIMENTS

For example, in each of the embodiments described above, the fluid sensor is a flow rate sensor that measures the flow rate of the fluid, but may be a pressure sensor that measures the pressure of the fluid.

Moreover, in addition to the configuration in which the discharge resistor 7 is connected in parallel to the piezo actuator 32 (piezo stack 32a), the piezo stack 32a may be connected in series so that the charge in the piezo stack 32a can be discharged when it is connected to the control power supply or when the signal line of the piezo stack is short-circuited.

Furthermore, in the above-described embodiment, the fluid control device 100 has a configuration in which the main unit 10 and the control board 5 are separated, but the main unit 10 and the control board 5 may not be separated. Specifically, the control board 5 may also be housed in the cover 6 and packaged that way.

In addition, various modifications and combinations of the embodiments may be made as long as they do not contradict the aim of the present invention.

### LIST OF REFERENCE CHARACTERS

100: fluid control device
10: main unit
3: fluid control valve
32: piezo actuator
32a: piezo stack
32b: case
32c: power supply terminal part
4: fluid sensor (flow rate sensor)
5: control board
7: discharge resistor
71: substrate
71h: through hole
72: resistive film
8: internal board (relay board)
K: connector cable
C: connection connector
1000: vaporization system
200: vaporizer part

1. A fluid control device comprising:
a fluid control valve driven by a piezo actuator,
a fluid sensor which measures a pressure or a flow rate of a fluid,
a control board which controls the fluid control valve based on a measured value measured by the fluid sensor, and
a discharge resistor provided on a component different from the control board.

2. The fluid control device according to claim 1, wherein
the discharge resistor is connected in parallel with the piezo actuator.

3. The fluid control device according to claim 1, wherein
the control board and a main unit which has the fluid control valve and the fluid sensor are separated, and
the discharge resistor is provided in the main unit.

4. The fluid control device according to claim 1, wherein
the discharge resistor is provided in a power supply terminal part which extends from a case which accommodates a piezo stack of the piezo actuator.

5. The fluid control device according to claim 4, wherein
the discharge resistor is formed by forming a resistive film on a substrate made of an insulating material, and
the substrate is formed with a through hole to be attached to the power supply terminal part.

6. The fluid control device according to claim 1, wherein
the discharge resistor is provided within a case containing a piezo stack of the piezo actuator.

7. The fluid control device according to claim 3, wherein
the main unit has a connection cable or a connector connected to the control board, and
the discharge resistor is provided on the connection cable or the connector.

8. The fluid control device according to claim 3, wherein
the main unit has an internal board which processes signals from the fluid sensor, and
the discharge resistor is provided on the internal substrate.

9. A vaporization system comprising;
a vaporizer part for vaporizing a liquid material,
and a fluid control device for controlling a flow rate of gas vaporized by the vaporizer part, wherein the fluid control device is one according to claim 1.

10. A piezo actuator used for driving a fluid control valve in a fluid control device, the fluid control device comprising:
the fluid control valve,
a fluid sensor that measures a pressure or a flow rate of a fluid,
a control board that controls the fluid control valve based on a measured value measured by the fluid sensor, and
a discharge resistor provided on a component different from the control board, wherein
the discharge resistor is connected in parallel to a power supply terminal extending from a case housing a piezo stack of the piezo actuator.

11. The piezo actuator according to claim 10, wherein
the discharge resistor is configured by forming a resistive film on a substrate made of an insulating material, and
the substrate is formed with a through hole to be attached to the power supply terminal part.
